(19) United States
(12) Patent Application Publication
(10) Pub. No.: US 2023/0238964 A1
(43) Pub. Date: Jul. 27, 2023

(54) TRANSMISSION CIRCUIT

(71) Applicant: ROHM CO., LTD., Kyoto-shi (JP)

(72) Inventor: Masanobu TSUJI, Kyoto-shi (JP)

(21) Appl. No.: 18/296,195

(22) Filed: Apr. 5, 2023

Related U.S. Application Data
(63) Continuation of application No. PCT/JP2021/036572, filed on Oct. 4, 2021.

(30) Foreign Application Priority Data
Oct. 7, 2020 (JP) 2020-169767

(51) Int. Cl. H03K 19/0175; H03K 17/691; H03K 5/01

(52) U.S. Cl. CPC H03K 19/017545; H03K 17/691; H03K 5/01; H03K 19/20

(57) ABSTRACT

A transformer includes a primary winding and a secondary winding. A transmitting circuit is coupled to a primary winding of a transformer and supplies a current signal to the primary winding with a polarity that changes in response to a change of the input signal level. A latch circuit is arranged such that its set terminal is coupled to one end of the secondary winding of the transformer, and its reset terminal is coupled to the other end of the secondary winding of the transformer. A first switch is arranged between a common voltage node at which a common voltage occurs and the set terminal. When the output of the latch circuit is high, the first switch is turned on. A second switch is arranged between the common voltage node and the reset terminal. When the output of the latch circuit is low, the second switch is turned on.

### CROSS REFERENCES TO RELATED APPLICATIONS

The present invention claims priority under 35 U.S.C. § 119 to Japanese Application, 2020-169767, filed on Oct. 7, 2020, the entire contents of which being incorporated herein by reference.

### BACKGROUND

### 1. Technical Field

The present disclosure relates to a signal transmission between two insulated regions.

### 2. Description of the Related Art

In-vehicle systems, industrial systems, medical device systems, etc., such as commercial power supply systems, motor systems, measurement device systems, etc., require high electrical isolation in digital signal transmission between semiconductor chips (i) to protect the human body and devices from surge current and high voltage, (ii) to provide noise isolation so as to prevent abnormal operation, and (iii) to protect transistors in signal transmission between regions with a high voltage difference.

Examples of signal transmission proposed so as to provide isolation include wireless signal transmission, photocoupler signal transmission, capacitor signal transmission, transformer signal transmission, Giant Magneto Resistive (GMR) signal transmission, etc.

Among the signal transmission methods described above, the transformer signal transmission method has many advantages from the viewpoints of transmission rate, power consumption, and Common Mode Transient Immunity (CMTI). FIGS. 1A through 1D are diagrams for explaining signal transmission using the transformer signal transmission method.

FIG. 1A shows a pulse set/reset transmission circuit 10. On the primary side, a pulse generator 12 generates a set pulse Is in response to a positive edge of the input signal Dᵢₙ, so as to drive a primary winding of a transformer T1. Furthermore, the pulse generator 12 generates a reset pulse I_{R} in response to a negative edge of the input signal Dᵢₙ so as to drive a primary winding of a transformer T2.

Secondary windings of the transformers T1 and T2 are coupled to a set/reset (SR) latch 14. The SR latch 14 is set by the set pulse Is received via the transformer T1. Furthermore, the SR latch 14 is reset by the reset pulse I_{R} received via the transformer T2. The SR latch 14 generates an output signal Dₒᵤₜ according to the input signal Dᵢₙ.

FIG. 1B shows a transmission circuit 20 using a pulse count method. In the pulse count method, the positive edge and the negative edge of the input signal Dᵢₙ are each encoded into a different number of pulse signals, and the pulse signals thus encoded are transmitted. Specifically, on the primary side, the pulse generator 22 encodes a positive edge of the input signal Dᵢₙ into a transmission signal I_{TX} including a predetermined number of pulses (e.g., two pulses). On the other hand, the pulse generator 22 encodes a negative edge into a transmission signal I_{TX} including a predetermined number of pulses (e.g., one pulse). The transmission signal I_{TX} is transmitted to the secondary side via a single transformer T1. A pulse decoder 24 on the secondary side counts the number of pulses included in a received signal and decodes the received signal into an output signal Dₒᵤₜ. Specifically, when the pulse decoder 24 detects two pulse signals, the pulse decoder 24 switches the output signal Dₒᵤₜ to the high level. When the pulse decoder 24 detects one pulse signal, the pulse decoder 24 switches the output signal Dₒᵤₜ to the low level.

FIG. 1C shows a transmission circuit 30 using a pulse polarity method. In the pulse polarity method, the positive edge and the negative edge of the input signal Dᵢₙ are each converted into a pulse current having a different polarity (direction), and the pulse current thus converted is transmitted via a transformer T1. Specifically, a driver 32 on the primary side generates a transmission signal I_{TX} including a pulse current with a first polarity in response to a positive edge of the input signal Dᵢₙ. On the other hand, the driver 32 generates a transmission signal I_{TX} including a pulse current with a second polarity in response to a negative edge of the input signal Dᵢₙ. With this, the driver 32 drives the primary winding of the transformer T1. A receiver 34 generates an output signal Dₒᵤₜ based on the polarity of a current I_{RX} that flows through the secondary winding of the transformer T2. Specifically, when the current I_{RX} having the first polarity flows, the receiver 34 switches the output signal Dₒᵤₜ to the high level. When the current I_{RX} having the second polarity flows, the receiver 34 switches the output signal Dₒᵤₜ to the low level.

FIG. 1D shows a transmission circuit 40 using a modulation/demodulation method. In the modulation/demodulation method, a carrier signal is modulated according to an input signal Dᵢₙ, and the carrier signal thus modulated is transmitted. Examples of such a modulation/demodulation method include on/off keying (OOK). During a period in which the input signal Dᵢₙ is set to the high level, a modulator 42 generates a pulse signal. During a period in which the input signal Dᵢₙ is set to the low level, the modulator 42 stops the pulse signal. During a period in which the pulse signal is generated, a demodulator 44 generates an output signal Dₒᵤₜ with the high level. On the other hand, during a period in which the pulse signal is not generated, the demodulator 44 generates an output signal Dₒᵤₜ with the low level. The demodulation method is not restricted in particular. Frequency shift keying (FSK) or the like may be employed as the demodulation method.

The pulse set/reset method shown in FIG. 1A requires two transformers. This involves the largest area among the methods described above. However, the pulse set/reset method requires no unnecessary signal transmission, thereby enabling low current consumption in proportion to signal speed. In particular, such a method can be supported using a digital circuit that requires no steady current. Accordingly, in particular, when a signal is transmitted with a low signal transmission rate, this provides low current consumption. Furthermore, such an arrangement does not involve encoding and modulation/demodulation. Accordingly, such an arrangement is capable of supporting low propagation delay and high-speed transmission. However, the transmission rate is limited due to skew variation between the low signal transmission path and the high signal transmission path.

The pulse count method shown in FIG. 1B requires only a single transformer, thereby requiring a reduced circuit area. However, such an arrangement transmits multiple pulses, leading to an increase in current consumption as compared with the pulse set/reset method. Furthermore, this requires a period of two pulses or more, leading to a limited transmission rate. In addition, retiming in decoding is required, leading to an increase in propagation delay.

In the pulse polarity method shown in FIG. 1C, such an arrangement requires only a single transformer. Furthermore, this allows the transmitting/receiving circuit to have a simple and compact configuration, thereby providing a small circuit area. However, a steady current is required for supplying a bias current in the reception-side circuit and for generating a common voltage (reference voltage). Accordingly, this leads to an increase in current consumption in a low-speed operation as compared with the pulse set/reset method. Furthermore, in a case in which the current for the reception-side circuit is reduced, this leads to a reduced transmission rate and degraded noise resistance. However, such an arrangement is capable of providing the shortest signal path, thereby providing advantages of low propagation delay and providing high-speed transmission in a simple manner.

In the modulation/demodulation method shown in FIG. 1D, such an arrangement requires only a single transformer, thereby providing an advantage of a small area. As a tradeoff problem, such an arrangement involves an increase in area due to the demodulation circuit and peripheral circuits thereof. In order to transmit and receive a carrier signal, the operation current is large when a signal is transmitted at a low speed. In addition, the secondary side receiving circuit requires a steady current as a bias current. The carrier frequency involves a problem of EMI degradation, which must be handled using a spread spectrum method or the like. However, this readily leads to an increased circuit area and increased operation current consumption. The modulation/demodulation method shown in FIG. 1D is preferably employed in medium- or high-speed transmission.

As described above, in digital signal transmission across a galvanic isolation barrier using a transformer according to a conventional technique, there are tradeoff problems between the area, current consumption, propagation delay, and transmission rate.

### SUMMARY

The present disclosure has been made in order to solve such a problem.

A transmission circuit according to an embodiment of the present disclosure includes: a transformer including a primary winding and a secondary winding; a transmitting circuit coupled to the primary winding of the transformer, and structured to transmit a current signal to the primary winding with a polarity that changes in response to a change of the level of an input signal; a latch circuit having a set terminal coupled to one end of the secondary winding of the transformer, and a reset terminal coupled to the other end of the secondary winding of the transformer; a first switch coupled between a common voltage node at which a common voltage occurs and the set terminal, and structured to turn on when an output of the latch circuit is high; and a second switch coupled between the common voltage node and the reset terminal, and structured to turn on when the output of the latch circuit is low.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIGS. 1A through 1D are diagrams for explaining signal transmission using a transformer method;

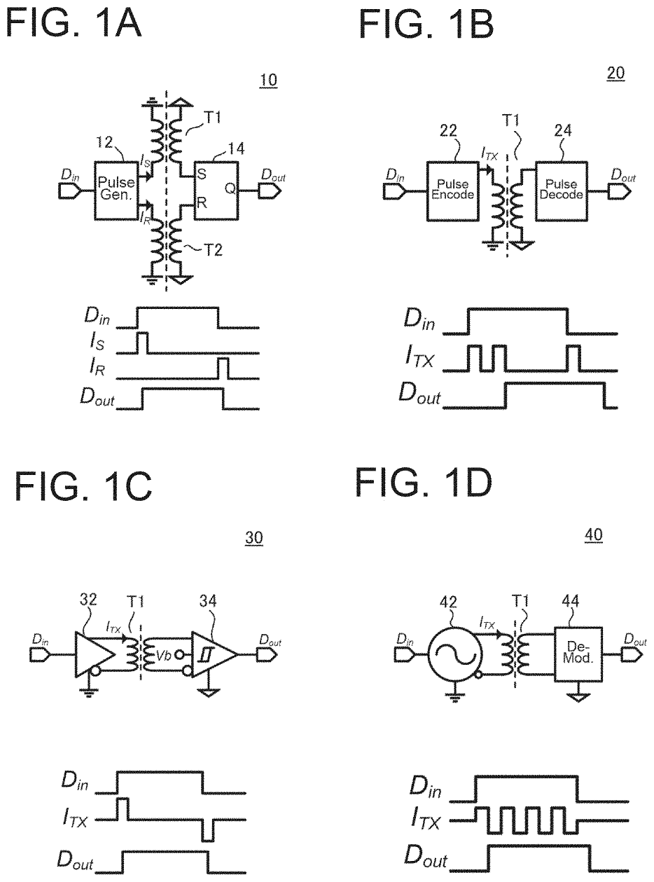

FIG. 2 is a circuit diagram of a transmission circuit according to an embodiment;

FIGS. 3A through 3C are diagrams for explaining signal transmission of the transmission circuit;

FIGS. 4A and 4B are equivalent circuit diagrams showing two states ϕ_{A} and ϕ_{B} of the transmission circuit;

FIG. 5 is a time chart showing data transmission of the transmission circuit;

FIG. 6A is a diagram showing the operation of a conventional pulse set/reset transmission circuit;

FIG. 6B is a diagram showing the operation of the transmission circuit shown in FIG. 2;

FIGS. 7A and 7B are diagrams for explaining a mismatch between the primary side and the secondary side of the transmission circuit and its resolution;

FIG. 8 is a circuit diagram showing a transmission circuit according to an example 1;

FIG. 9 is a time chart showing the operation of the transmission circuit shown in FIG. 8;

FIG. 10 is a circuit diagram showing a transmission circuit according to an example 2;

FIG. 11 is a time chart showing the operation of the transmission circuit shown in FIG. 10;

FIG. 12 is a circuit diagram showing a transmission circuit according to an example 3;

FIG. 13 is a time chart showing the operation of the transmission circuit shown in FIG. 12;

FIG. 14 is a circuit diagram showing a transmission circuit according to an example 4;

FIG. 15 is a time chart showing the operation of the transmission circuit shown in FIG. 14;

FIG. 16 is a circuit diagram showing a transmission circuit according to an example 6;

FIG. 17 is a time chart showing the operation of the transmission circuit shown in FIG. 16;

FIG. 18 is a circuit diagram showing a transmission circuit according to an example 7;

FIG. 19 is a time chart showing the operation of the transmission circuit shown in FIG.

FIGS. 20A through 20E are diagrams each showing a first mounting example of the transmission circuit;

FIGS. 21A through 21E are diagrams each showing a second mounting example of the transmission circuit; and

FIG. 22 is diagrams showing a third mounting example of the transmission circuit.

### DETAILED DESCRIPTION

### Outline of Embodiments

An outline of several example embodiments of the disclosure follows. This outline is provided for the convenience of the reader to provide a basic understanding of such embodiments and does not wholly define the breadth of the disclosure. This outline is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

A transmission circuit according to one embodiment includes: a transformer including a primary winding and a secondary winding; a transmitting circuit coupled to the primary winding of the transformer, and structured to transmit a current signal to the primary winding with a polarity that changes in response to a change of the level of an input signal; a latch circuit having a set terminal coupled to one end of the secondary winding of the transformer, and a reset terminal coupled to the other end of the secondary winding of the transformer; a first switch coupled between a common voltage node at which a common voltage occurs and the set terminal, and structured to turn on when an output of the latch circuit is high; and a second switch coupled between the common voltage node and the reset terminal, and structured to turn on when the output of the latch circuit is low.

With this configuration in which the first switch and the second switch are controlled according to the state of the latch circuit so as to control the state of the secondary winding, such an arrangement requires only a single transformer to provide an operation equivalent to that provided by a conventional pulse set/reset transmission circuit. That is to say, this configuration requires only a single transformer to provide an advantage of such a pulse set/reset transmission circuit. This allows the circuit area to be reduced. Furthermore, this is capable of solving a transmission rate limitation due to skew variation between two transformers. Accordingly, this provides transmission with a higher rate.

In one embodiment, the current signal may be set to a first polarity during a period in which the input signal is set to a first level and may be set to a second polarity during a period in which the input signal is set to a second level.

In one embodiment, the current signal may include a pulse current having a first polarity that corresponds to a positive edge of the input signal and a pulse current having a second polarity that corresponds to a negative edge of the input signal. In this case, such an arrangement does not involve consumption of a steady current. Such an arrangement has an advantage from the viewpoint of power consumption.

In one embodiment, the transmission circuit may further include a switch control unit structured to control the first switch and second switch according to the state of the latch circuit. After a transition of a pulse current having the first polarity, the switch control unit may turn off the second switch. After a transition of a pulse current having the second polarity, the switch control unit may turn off the first switch. With this, such an arrangement is capable of suppressing a rise of the terminal voltage of the secondary winding, thereby providing improved stability.

In one embodiment, when a predetermined time period elapses after the first switch turns on, the switch control unit may turn off the second switch. Also, when a predetermined time period elapses after the second switch turns on, the switch control unit may turn off the first switch. With this arrangement, a period in which both the first switch and the second switch are turned on is inserted so as to fix the voltages at the set terminal and the reset terminal. This is capable of inhibiting state transition of the latch circuit, thereby providing the circuit operation with further improved stability.

In one embodiment, as the common voltage, the ground voltage may be employed. Also, the first switch and the second switch may each be configured as an NMOS transistor.

In one embodiment, as the common voltage, the power supply voltage may be employed. Also, the first switch and the second switch may each be configured as a PMOS transistor.

In one embodiment, the latch circuit may include a first NOR gate and a second NOR gate cross-coupled to each other.

In one embodiment, the latch circuit may include a first NAND gate and a second NAND gate cross-coupled to each other.

In one embodiment, as the common voltage, the ground voltage may be employed. Also, the first switch and the second switch may each be configured as an NMOS transistor. The transmission circuit may further include a first inverter having its input node receiving the inverted output signal of the latch circuit and its output node coupled to the gate of the first switch, and a second inverter having its input node receiving the output signal of the latch circuit and its output node coupled to the gate of the second switch.

In one embodiment, as the common voltage, the ground voltage may be employed. Also, the first switch and the second switch may each be configured as an NMOS transistor. The transmission circuit may further include: a first NAND gate having its first input node receiving the inverted output signal of the latch circuit and its output node coupled to the gate of the first switch; a first delay circuit structured to delay the output of the first NAND gate; a second NAND gate having its first input node receiving the output signal of the latch circuit, its second input node receiving the output signal of the first delay circuit, and its output node coupled to the gate of the second switch; and a second delay circuit structured to delay the output of the second NAND gate, and to supply the output thus delayed to the second input node of the first NAND gate.

In one embodiment, as the common voltage, the power supply voltage may be employed. Also, the first switch and the second switch may each be configured as a PMOS transistor. The transmission circuit may further include a third inverter having its input node receiving the output signal of the latch circuit and its output node coupled to the gate of the first switch, and a fourth inverter having its input node receiving an inverted output signal of the latch circuit, and its output node coupled to the gate of the second switch.

In one embodiment, the transmitting circuit may include: a first output stage structured as a push-pull output stage, and having an output node coupled to one end of the first winding; a second output stage structured as a push-pull output stage, and having an output node coupled to the other end of the primary winding; and a pre-driver structured to control the first output stage and the second output stage with opposite polarities according to the input signal.

In one embodiment, the pre-driver may include: a delay circuit structured to delay the input signal; a NOR gate structured to generate an exclusive logical OR of the input signal and an output of the delay circuit; a first AND gate structured to drive the first output stage based on the logical AND of an inverted signal of the input signal and an output of the delay circuit; and a second AND gate structured to drive the second output stage based on the logical AND of the input signal and the output of the delay circuit. This arrangement is capable of pulse driving the transformer.

In one embodiment, the pre-driver may include a delay circuit structured to delay the input signal. Also, the pre-driver may control the first output stage according to an output of the delay circuit and may control the second output stage according to the input signal. With this arrangement, this allows the number of transistor transitions to be reduced. Furthermore, this arrangement uses no pulses in the signal path. This provides low power consumption. Furthermore, this facilities high-speed data transmission.

In one embodiment, the transmitting circuit may include: a first high-side transistor having a drain coupled to one end of the primary winding, and a source receiving a power supply voltage; a first low-side transistor having a drain thereof coupled to one end of the primary winding, and a source grounded; a second high-side transistor having a drain coupled to the other end of the primary winding, and a source receiving the power supply voltage; a second low-side transistor having a drain coupled to the other end of the primary winding, and a source grounded; a common transistor coupled in parallel with the primary winding; and a pre-driver structured to drive the first high-side transistor, the first low-side transistor, the second high-side transistor, the second low-side transistor, and the common transistor according to the input signal. With this arrangement, by reducing the number of times the high-side transistor is switched, this is capable of suppressing power consumption. Furthermore, with such an arrangement employing the common transistor, this is capable of suppressing a change of voltage accompanying the switching of the high-side transistor.

### EMBODIMENTS

Description will be made below regarding preferred embodiments with reference to the drawings. The same or similar components, members, and processes are denoted by the same reference numerals, and redundant description thereof will be omitted as appropriate. The embodiments have been described for exemplary purposes only and are by no means intended to restrict the present invention. Also, it is not necessarily essential for the present invention that all the features or a combination thereof be provided as described in the embodiments.

In the present specification, the state represented by the phrase “the member A is coupled to the member B” includes a state in which the member A is indirectly coupled to the member B via another member that does not substantially affect the electrical connection between them, or that does not damage the functions or effects of the connection between them, in addition to a state in which they are physically and directly coupled.

Similarly, the state represented by the phrase “the member C is provided between the member A and the member B” includes a state in which the member A is indirectly coupled to the member C, or the member B is indirectly coupled to the member C, via another member that does not substantially affect the electrical connection between them, or that does not damage the functions or effects of the connection between them, in addition to a state in which they are directly coupled.

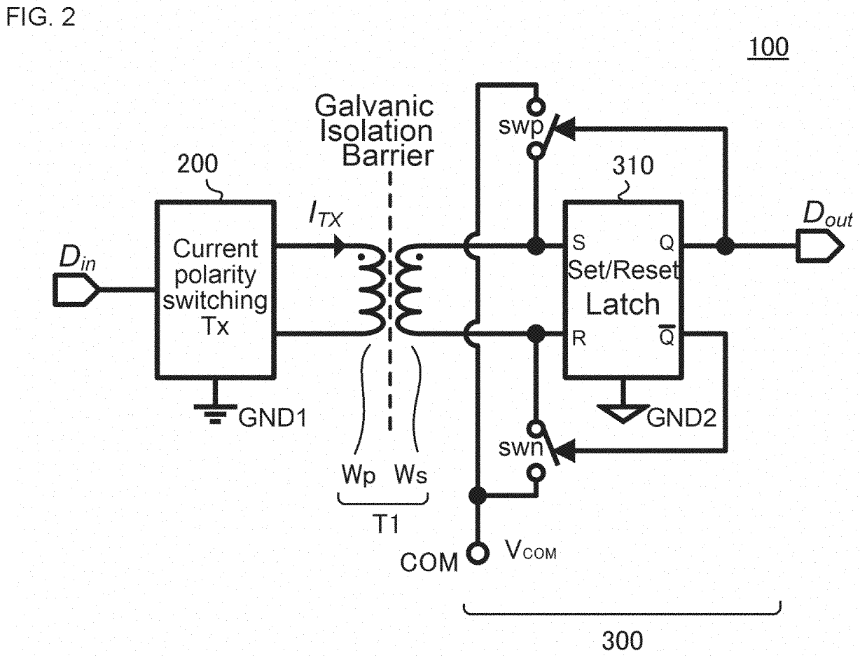

FIG. 2 is a circuit diagram of a transmission circuit 100 according to an embodiment. The transmission circuit 100 includes a transformer T1, a transmitting circuit 200, and a receiving circuit 300. The transformer T1 includes a primary winding Wp and a secondary winding Ws.

The transmission circuit 200 is coupled to the primary winding Wp of the transformer T1 and supplies a current signal I_{TX} to the primary winding Wp with a polarity (direction) that changes in response to a change of the level of the input signal Dᵢₙ.

A latch circuit 310 is arranged such that its set terminal (S) is coupled to one end of the secondary winding Ws of the transformer T1, and its reset terminal (R) is coupled to the other end of the secondary winding Ws of the transformer T1.

A first switch swp is provided between the set terminal (S) and a common voltage node COM at which the common voltage V_{COM} occurs. When the output of the latch circuit 310 is set to the high level, the first switch swp is turned on. A second switch swn is provided between the common voltage node COM and the reset terminal (R). When the output of the latch circuit 310 is set to the low level, the second switch swn is turned on. Either one of the ground voltage GND2 or the power supply voltage may be employed as the common voltage V_{COM} as described later.

The logical polarity and configuration of the latch circuit 310 are not restricted in particular so long as the latch circuit 310 includes two inputs, i.e., a set input and a reset input.

The above is the configuration of the transmission circuit 100. Next, description will be made regarding the operation thereof.

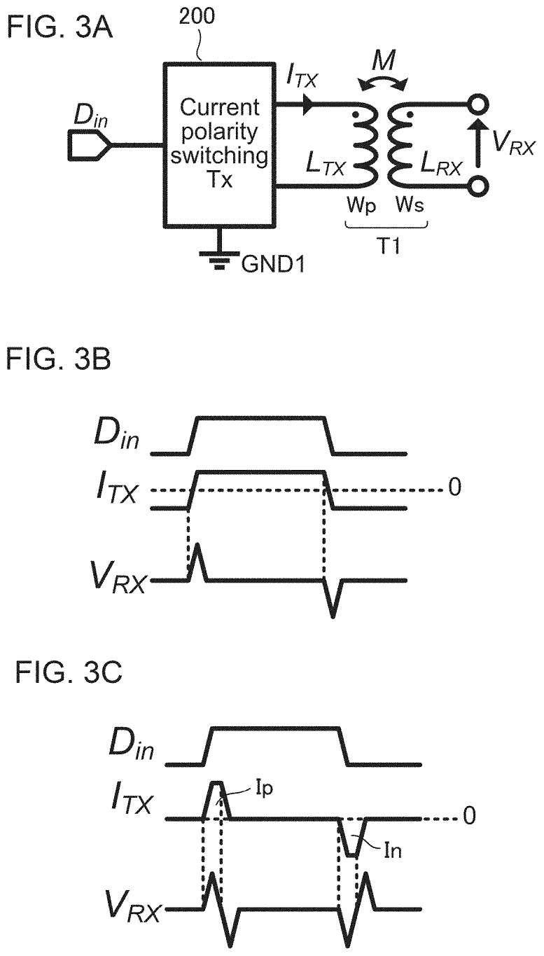

FIGS. 3A through 3C are diagrams for explaining signal transmission in the transmission circuit 100. The voltage V_{RX} that occurs across the secondary winding Ws of the transformer T1 is represented by Expression (1).

V_{RX}=M·dI_{TX}/dt (1)

M is the transconductance, which is represented by M=k√(L_{TX}·L_{RX}), where k is the coupling coefficient.

The transmission circuit 200 switches the direction (polarity) of the primary current I_{TX} that flows through the primary winding Wp of the transformer T1 according to the input signal Dᵢₙ. There are two conceivable operation methods for this.

FIG. 3B shows a non-pulse transmission method. In the non-pulse transmission method, during a period in which the input signal Dᵢₙ is set to a first level (high), the current signal I_{TX} is set to a first polarity (e.g., positive). During a period in which the input signal Dᵢₙ is set to a second level (low), the current signal I_{TX} is set to a second polarity (e.g., negative). The voltage V_{RX} of the secondary winding Ws is generated as a positive pulse according to a positive edge of the input signal Dᵢₙ. Furthermore, the voltage V_{RX} is generated as a negative pulse according to a negative edge of the input signal Dᵢₙ.

FIG. 3C shows a pulse transmission method. In the pulse transmission method, the current signal I_{TX} includes a first polarity (positive) pulse current Ip that corresponds to a positive edge of the input signal Dᵢₙ and a second polarity (negative) pulse current In that corresponds to a negative edge of the input signal Dᵢₙ. The voltage V_{RX} across the secondary winding Sw includes a preceding positive pulse and a subsequent negative pulse according to a positive edge of the input signal Dᵢₙ. Furthermore, the voltage V_{RX} across the secondary winding Ws includes a preceding negative pulse and a subsequent positive pulse according to a negative edge of the input signal Dᵢₙ.

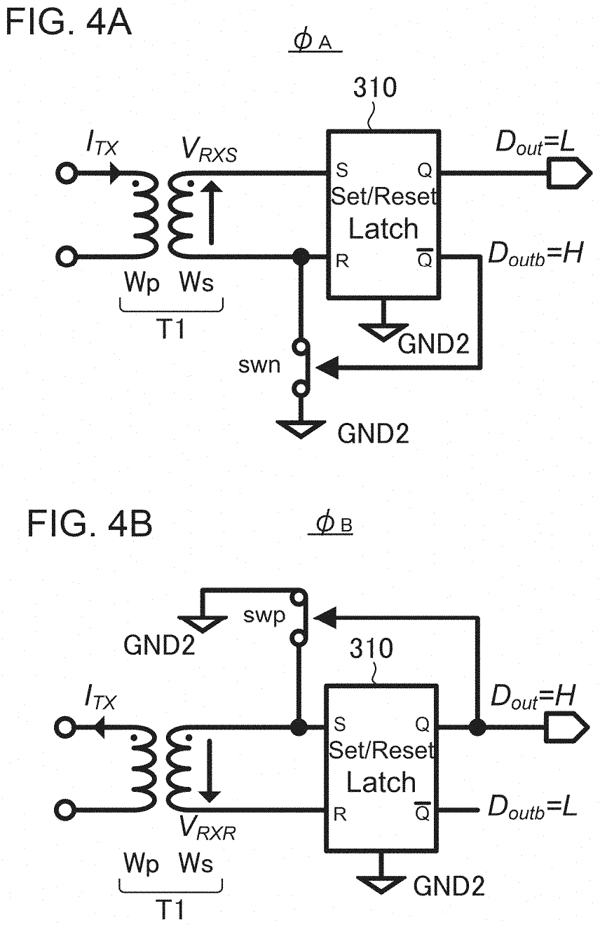

FIGS. 4A and 4B are equivalent circuit diagrams of the transmission circuit 100 in two states ϕ_{A} and ϕ_{B}. Description will be made below assuming that the common voltage node COM is configured as the ground GND2. In the first state ϕ_{A} shown in FIG. 4A, the output Dₒᵤₜ of the latch circuit 310 is set to the low level, the inverted output signal D_{outb} is set to the high level, and the second switch swn is turned on. When the second switch swn is turned on, the reset terminal side of the secondary winding Ws is fixed to the ground voltage GND2. In the first state ϕ_{A}, the latch circuit 310 can be set according to the voltage V_{RXS} that occurs on the set terminal side of the secondary winding Ws.

In the second state ϕ₃ shown in FIG. 4B, the output signal Dₒᵤₜ of the latch circuit 310 is set to the high level, the inverted input signal D_{outb} is set to the low level, and the first switch swp is turned on. When the first switch swp is turned on, the set terminal side of the secondary winding Ws is fixed to the ground voltage GND2. In the second state ϕ_{B}, the latch circuit 310 can be reset according to the voltage V_{RXR} that occurs on the reset terminal side of the secondary winding Ws.

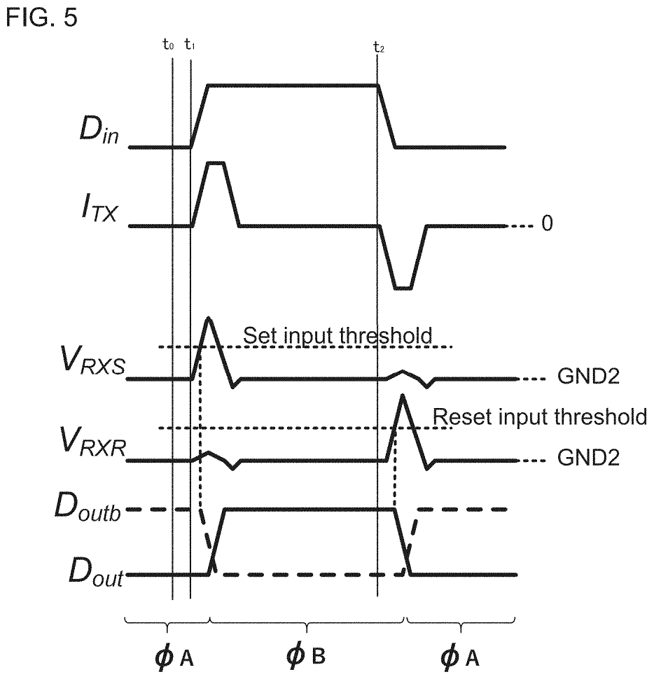

FIG. 5 is a time chart of data transmission of the transmission circuit 100. Here, the pulse transmission method is shown. Before the time point to, the transmission circuit 100 is set to the first state ϕ_{A}. When the input signal Dᵢₙ transits to the high level at the time point t₁, a positive polarity pulse current I_{TX} is generated. In response to the pulse current I_{TX}, the voltage V_{RX} represented by Expression (1) occurs across both ends of the secondary winding Ws. In the first state ϕ_{A}, the voltage V_{RXR} at the reset terminal is fixed to the ground GND2. Accordingly, the voltage V_{RXS} at the set terminal rises. When the voltage V_{RXS} exceeds a threshold value of the set side of the latch circuit 310, the latch circuit 310 is set, the inverted output signal D_{outb} transits to the low level, and the output signal Dₒᵤₜ transits to the high level. As a result, the transmission circuit 100 is switched to the second state ϕ₃ in which the set terminal is fixed to the ground GND2.

When the input signal Dᵢₙ transits to the low level at the time point t₂, a negative polarity pulse current I_{TX} is generated. In response to the pulse current I_{TX}, the voltage V_{RX} represented by Expression (1) occurs across both ends of the secondary winding Ws. In the second state ϕ_{B}, the voltage V_{RXS} at the set terminal is fixed to the ground GND2. Accordingly, the voltage V_{RXR} at the reset terminal rises. When the voltage V_{RXR} exceeds a threshold value of the reset side of the latch circuit 310, the latch circuit 310 is reset, the output signal Dₒᵤₜ transits to the low level, and the inverted output signal D_{outb} transits to the high level. As a result, the transmission circuit 100 is again switched to the first state ϕ_{A} in which the reset terminal is fixed to the ground GND2. The transmission circuit 100 repeats this operation so as to transmit the input signal Diu.

The above is the operation of the transmission circuit 100. Description will be made regarding the operation of the transmission circuit 100 as compared with a conventional pulse set/reset transmission circuit.

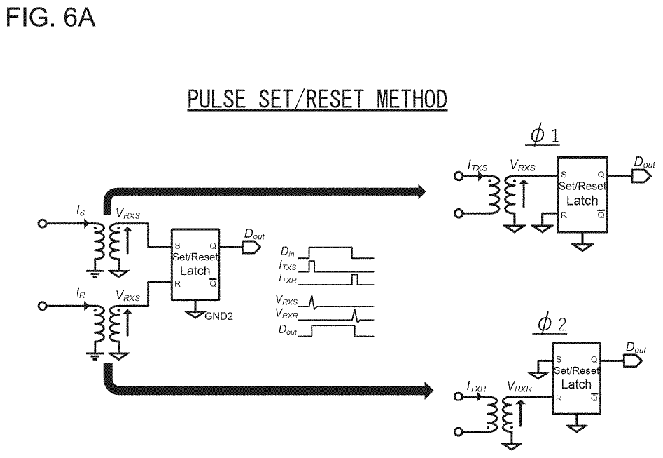

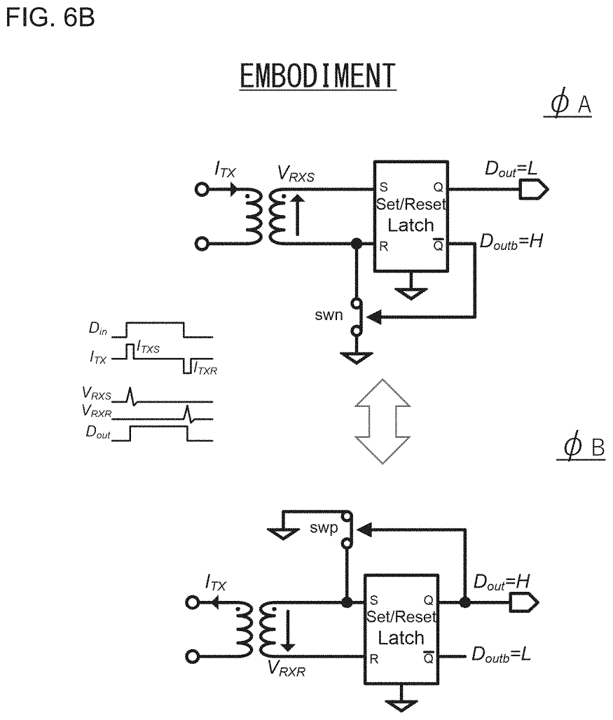

FIG. 6A is a diagram showing the operation of a conventional pulse set/reset transmission circuit. FIG. 6B is a diagram showing the operation of the transmission circuit 100 shown in FIG. 2.

FIG. 6A shows an equivalent circuit diagram showing a first state ϕ₁ in which a set pulse is transmitted and an equivalent circuit diagram showing a second state ϕ₂ in which a reset pulse is transmitted. In the first state ϕ₁, a reset terminal of a secondary-side SR latch is grounded to the ground GND2 so as to wait for a trigger voltage V_{RXS} to be supplied to a set terminal. In the second state ϕ₂, the set terminal of the secondary-side SR latch is grounded to the ground GND2 so as to wait for a trigger voltage V_{RXS} to be supplied to the reset terminal.

The first state ϕ₁ of the pulse set/reset transmission circuit shown in FIG. 6A is equivalent to the first state ϕ_{A} in the present embodiment shown in FIG. 6B. On the other hand, the second state ϕ₂ of the pulse set/reset transmission circuit shown in FIG. 6A is equivalent to the second state ϕ₃ in the present embodiment shown in FIG. 6B. That is to say, it can be understood that the transmission circuit 100 according to the present embodiment controls the first switch swp and the second switch swn according to the state of the latch circuit 310 so as to switch the state of the secondary winding Ws (common) in a time sharing manner, thereby replacing two transformers according to conventional techniques with a single transformer with a variable state. As described above, with the transmission circuit 100, this is capable of providing an operation that is equivalent to that of a conventional pulse set/reset transmission circuit using a single transformer T1.

With the present embodiment, such an arrangement requires only a single transformer to provide an advantage of such a pulse set/reset transmission circuit. Accordingly, this allows the circuit area to be reduced. Furthermore, this is capable of solving a transmission rate limitation due to skew variation between two transformers. Accordingly, this provides transmission with a higher rate.

Furthermore, such an arrangement is capable of expressing a binary value using the current polarity, thereby having an advantage in transmission rate, delay, and power consumption as compared with the pulse count method.

Moreover, with the transmission circuit 100, either one of the ends of the secondary winding Ws is fixed to the common voltage V_{COM} via the low-impedance switches swp and swn. As the common voltage V_{COM}, a stable electric potential (fixed voltage) such as the ground voltage GND2 (or power supply voltage VDD) may be employed. That is to say, there is no need to generate an intermediate electric potential using a bias circuit. Accordingly, this has an advantage that there is no need to design a time constant of such a bias circuit according to the data transmission rate. In addition, such a low-impedance common configuration allows noise effects to be reduced.

In a case in which an intermediate bias voltage is employed as the secondary-side common voltage, there is a need to configure the secondary-side circuit using an analog circuit, and steady current consumption is unavoidable. In contrast, with the present embodiment, as the common voltage V_{COM}, the ground voltage GND2 (or power supply voltage VDD) can be employed. Accordingly, this allows the secondary side receiving circuit 300 to be configured as a digital circuit (Set/Reset latch circuit) with a small circuit area without involving a steady current.

Furthermore, with the present embodiment, the latch circuit 310 can be directly used as an input of the receiving circuit 300. Such an arrangement naturally also has hysteresis characteristics, thereby providing noise resistance. A conventional arrangement requires a circuit for intentionally introducing such hysteresis characteristics. In contrast, with the present embodiment, this provides a simple configuration.

Moreover, this allows the number of transistor stages in the signal path to be reduced, thereby enabling low-delay and high-speed operation.

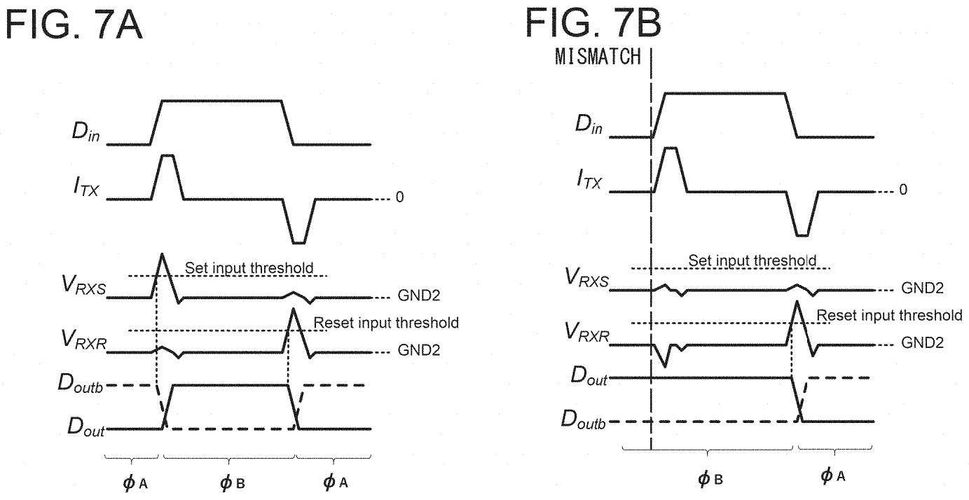

The transmission circuit 100 has the potential to involve a mismatch between the primary-side state (level of the input signal Dᵢₙ) and the secondary-side state (state of the latch circuit 310, i.e., the level of the output signal Dₒᵤₜ). FIGS. 7A and 7B are diagrams for explaining the mismatch between the primary side and the secondary side of the transmission circuit 100 and the resolution thereof.

FIG. 7A shows an initial state in which the input signal Dᵢₙ is set to the low level on the primary side, and the output signal Dₒᵤₜ is set to the low level on the secondary state (first state ϕ_{A}). In this state, consistency is maintained. In this case, the same operation as in FIG. 5 is executed.

FIG. 7B shows an initial state in which the input signal Dᵢₙ is set to the low level on the primary side, and the output signal Dₒᵤₜ is set to the low level on the secondary side (second state ϕ_{B}), which results in a mismatch. Even in this case, after the first transition of the input signal Dᵢₙ, the state is returned to a correct state. That is to say, such an arrangement ensures consistency.

Furthermore, the previous state is maintained as long as the voltages V_{RXS} and V_{RXR} input to the reset terminal do not exceed the respective input threshold values, thereby providing high noise resistance.

The present disclosure or the present invention encompasses various kinds of apparatuses and methods that can be regarded as a block configuration or a circuit configuration shown in FIG. 2, or otherwise that can be derived from the aforementioned description. That is to say, the present disclosure or the present invention is not restricted to a specific configuration. More specific description will be made below regarding example configurations and examples for clarification and ease of understanding of the essence of the present invention and the operation thereof. That is to say, the following description will by no means be intended to restrict the technical scope of the present invention.

### Example 1

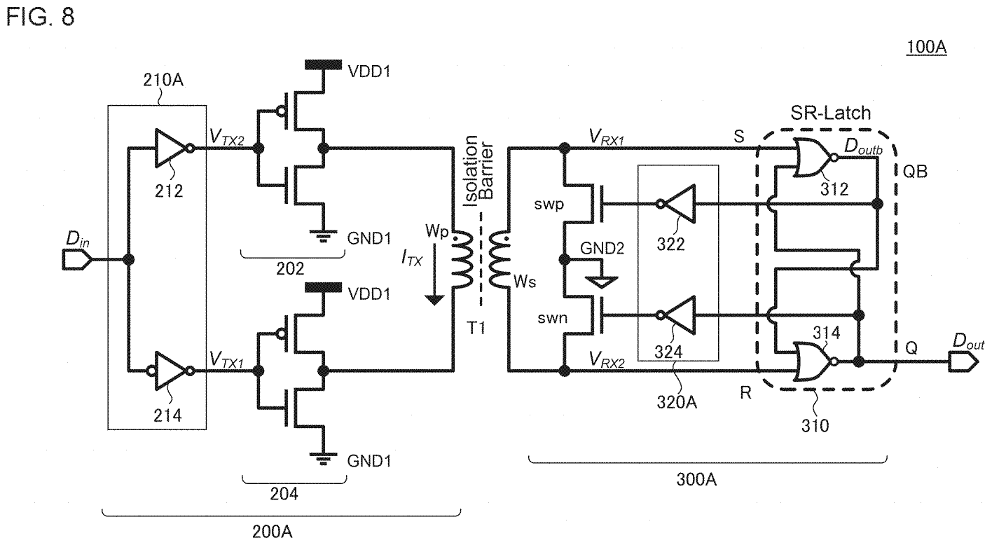

FIG. 8 is a circuit diagram of a transmission circuit 100A according to an example 1. A transmission circuit 200A includes a first output stage 202 and a second output stage 204 each configured as a push-pull output stage, and a pre-driver 210A. The output node of the first output stage 202 is coupled to one end of the primary winding Wp. The output node of the second output stage 204 is coupled to the other end of the primary winding Wp. The first output stage 202 and the second output stage 204 are each configured as a CMOS inverter. The two output stages 202 and 204 form an H-bridge circuit (full-bridge circuit).

The pre-driver 210A drives the first stage 202 and the second output stage 204 with opposite polarities in a complementary manner according to the input signal Dᵢₙ. For example, the pre-driver 210A includes: a driver 212 configured to generate a control signal having an inverted logical value that is the opposite of that of the input signal Dᵢₙ, and to supply the control signal thus generated to an input of the first output stage 202; and a driver 214 configured to generate a control signal having the same logical value as that of the input signal Dᵢₙ, and to supply the control signal thus generated to an input of the second output stage 204. With the transmission circuit 200A, this is capable of providing the non-pulse transmission method shown in FIG. 3B.

Next, description will be made regarding a secondary-side configuration. The receiving circuit 300A includes a latch circuit 310, a first switch swp, a second switch swn, and a switch control unit 320A.

In this example, as the common voltage V_{COM}, the ground voltage GND2 is employed. The first switch swp and the second switch swn are each configured as an NMOS transistor.

The latch circuit 310 is configured as a NOR latch including two NOR gates 312 and 314 cross-coupled to each other.

The switch control unit 320A controls the first switch swp and the second switch swn according to the state of the latch circuit 310.

The switch control unit 320A includes a first inverter 322 and a second inverter 324. The input node of the first inverter 322 is coupled to an inverted output QB of the latch circuit 310 and receives the inverted output signal D_{outb}. Furthermore, the output node of the first inverter 322 is coupled to the gate of the first switch swp. The input node of the second inverter 324 is coupled to the output Q of the latch circuit 310 and receives the output signal Dₒᵤₜ. The output node of the second inverter 324 is coupled to the gate of the second switch swn.

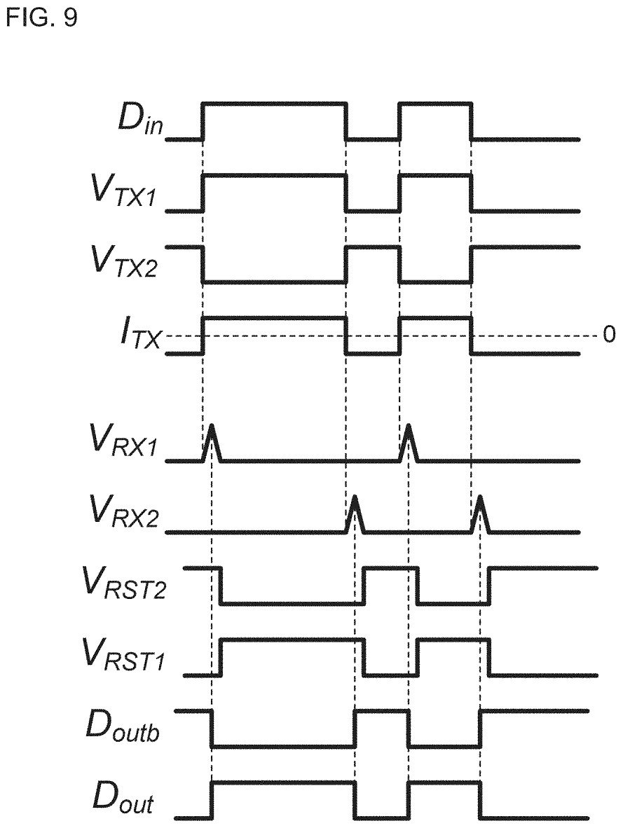

FIG. 9 is a time chart showing the operation of the transmission circuit 100A shown in FIG. 8. During the high period of the input signal Dᵢₙ, the current I_{TX} flows with the first polarity (positive). During the low period thereof, the current I_{TX} flows with the second polarity (negative). The voltage V_{RX} occurs across the secondary winding Ws according to Expression (1) in response to the change in the polarity of the current I_{TX}. With the transmission circuit 100A shown in FIG. 8, this allows a signal to be transmitted using the non-pulse transmission method.

### Example 2

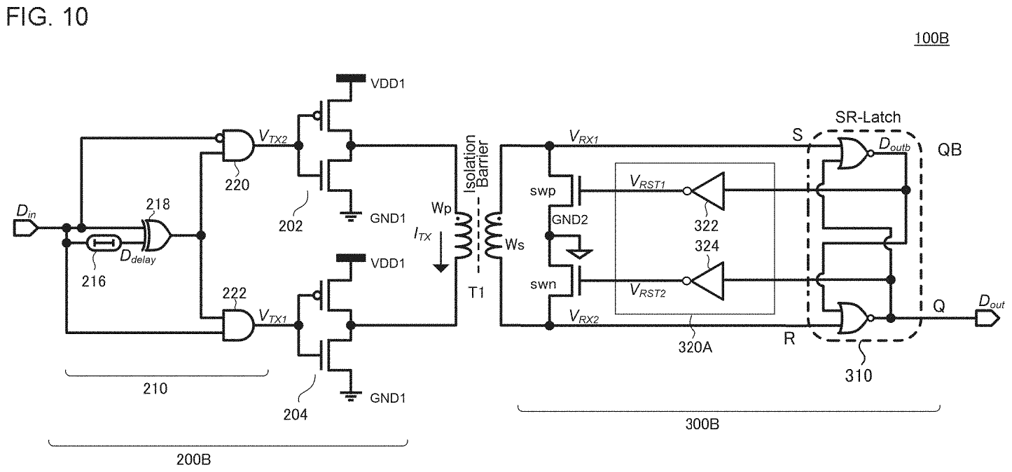

FIG. 10 is a circuit diagram of a transmission circuit 100B according to an example 2. The transmission circuit 100B is configured to use a pulse transmission method.

The transmission circuit 200B includes a first output stage 202, a second output stage 204, and a pre-driver 210B. The pre-driver 210B includes a delay circuit 216, a NOR gate 218, a first AND gate 220, and a second AND gate 222. The delay circuit 216 delays the input signal Dᵢₙ. The NOR gate 218 generates the exclusive logical OR of the input signal D_{IN} and the output D_{delay} of the delay circuit 216. The first AND gate 220 drives the first output stage 202 based on the logical AND of the inverted signal of the input signal Dᵢₙ and the output D_{delay} of the delay circuit 216. The second AND gate 222 drives the second output stage 204 based on the logical AND of the input signal Dᵢₙ and the output D_{delay} of the delay circuit 216. With the transmission circuit 200B, such an arrangement is capable of providing the pulse transmission method.

The receiving circuit 300B has the same configuration as that of the receiving circuit 300A according to the example 1. The receiving circuit 300B includes a latch circuit 310, a first switch swp, a second switch swn, and a switch control unit 320B. In this example, as the common voltage V_{COM}, the ground GND2 is employed. Furthermore, the first switch swp and the second switch swn are each configured as an NMOS transistor.

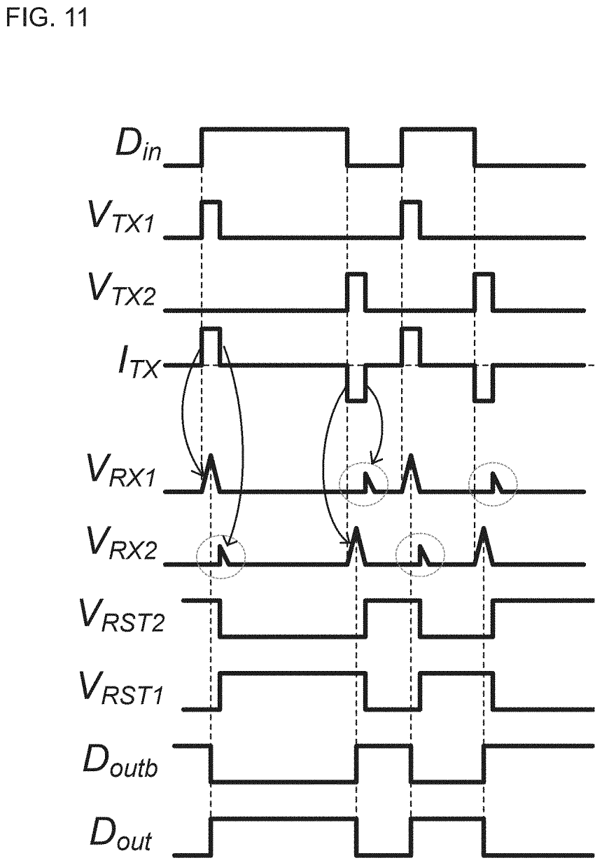

FIG. 11 is a time chart showing the operation of the transmission circuit 100B shown in FIG. 10. With the transmission circuit 100B, such an arrangement is capable of transmitting a signal using the pulse transmission method.

With the pulse transmission method, each current pulse I_{TX} changes in response to both the positive slope and the negative slope. Accordingly, a rebound readily occurs in the voltages V_{RX1} and V_{RX2}. Specifically, a surge occurs in the voltage V_{RX2} due to a rear edge (trailing edge) of a positive current pulse. Furthermore, a surge occurs in the voltage V_{RX1} due to a trailing edge of the negative current pulse. Such surges lead to noise. If the noise amplitude is smaller than each threshold value for the set and reset of the latch circuit 310, the transmission circuit 100B shown in FIG. 10 operates satisfactorily. Accordingly, as a typical arrangement, the trailing edge of each pulse is designed to provide a lower slew rate. In this case, such an arrangement requires an additional circuit.

It should be noted that, in a case in which the noise amplitude exceeds a threshold, this leads to an abnormal operation. In order to solve such a problem, in a case in which the noise amplitude is large, such an abnormal operation can be prevented using a technique described below in an example 3.

### Example 3

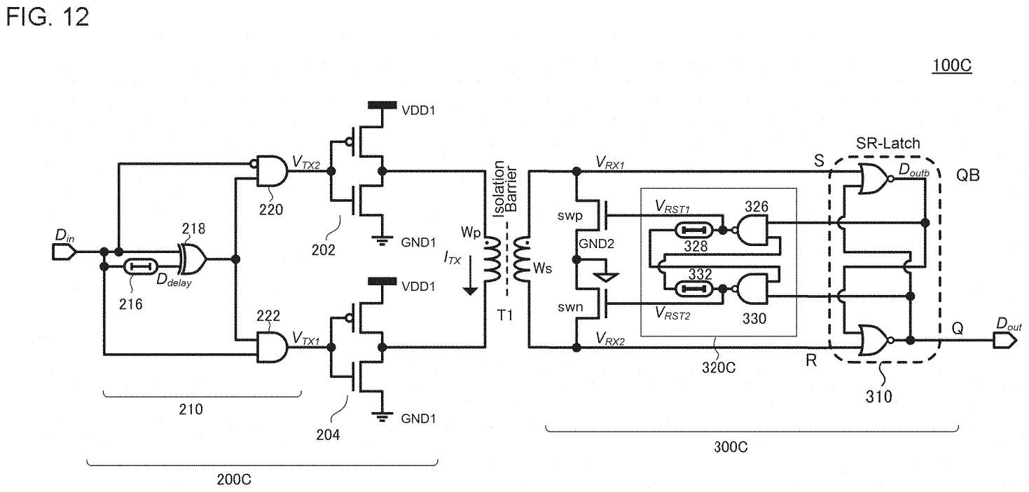

FIG. 12 is a circuit diagram of a transmission circuit 100C according to an example 3. A switch control unit 320C waits for the transition (trailing edge) of the current pulse I_{TX}, and subsequently turns off the first switch swp and the second switch swn. That is to say, the switch control unit 320C turns off the second switch swn after the transition of the pulse current I_{TX} having the first polarity and turns off the first switch swp after the transition of the pulse current I_{TX} having the second polarity.

Here, the switch control unit 320C may employ a simple delay. However, in this example, the switch control unit 320C employs a delay provided by a non-overlap circuit. After a predetermined time elapses after the first switch swp is turned on, the switch control unit 320C turns off the second switch swn. After a predetermined time, elapses after the second switch swn is turned on, the switch control unit 320C turns off the first switch swp. With this, a period in which both the first switch swp and the second switch swn are turned on is provided such that both the voltage V_{RX1} at the set terminal and the voltage V_{RX2} at the reset terminal are fixed to the ground GND2. This allows the signal to be further stabilized.

The switch control unit 320C includes a first NAND gate 326, a first delay circuit 328, a second NAND gate 330, and a second delay circuit 332.

The first input node of the first NAND gate 326 is coupled to the inverted output QB of the latch circuit 310 and receives the inverted output signal D_{outb}. The output node of the first NAND gate 326 is coupled to the gate of the first switch swp. The first delay circuit 328 delays the output V_{RST1} of the first NAND gate 326. The first input node of the second NAND gate 330 is coupled to the output Q of the latch circuit 310 and receives the output signal Dₒᵤₜ. The second NAND gate 330 has its second input node receiving the output signal of the first delay circuit 328, and its output node is coupled to the gate of the second switch swn. The second delay circuit 332 delays the output V_{RST2} of the second NAND gate 330 and supplies the output V_{RST2} thus delayed to the second input node of the first NAND gate 326.

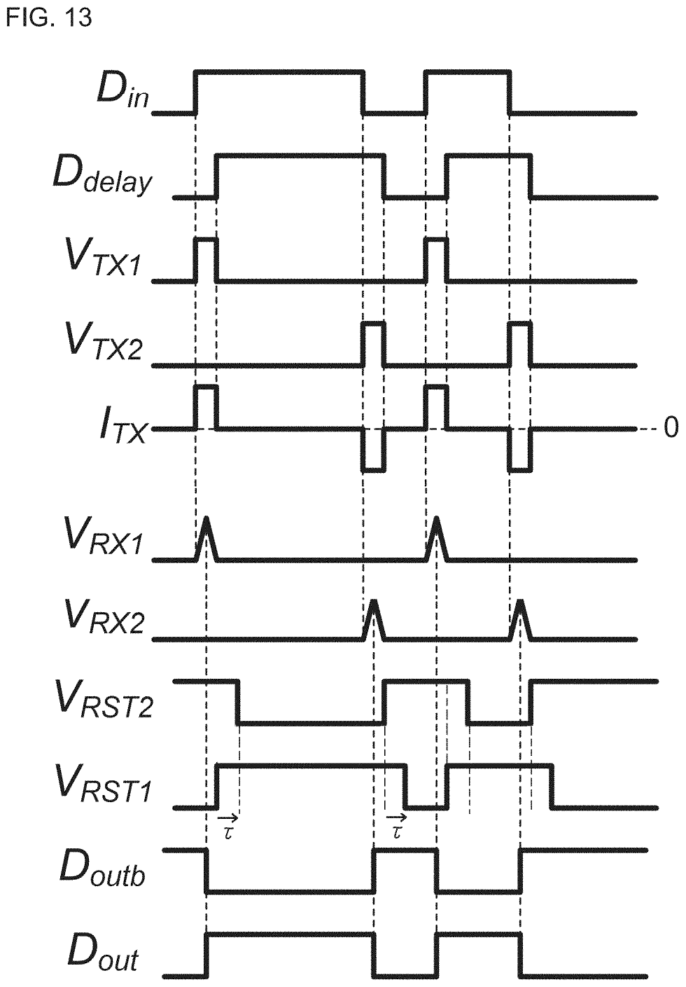

FIG. 13 is a time chart showing the operation of the transmission circuit 100C shown in FIG. 12. With this configuration, after a delay time τ elapses after the first switch swp is turned on according to the gate voltage V_{RST1} of the first switch swp becoming the high level, the gate voltage V_{RST2} of the second switch swn is set to the low level, thereby turning off the second switch swn.

Furthermore, after a delay time τ elapses after the second switch swn is turned on according to the gate voltage V_{RST2} of the second switch swn becoming the high level, the gate voltage V_{RST1} of the first switch swp is set to the low level, thereby turning off the first switch swp.

With the example 3, this arrangement is capable of reliably preventing a state transition from occurring in the latch circuit 310 due to a change in current of a trailing edge of the positive-polarity pulse current I_{TX} and due to a change in current of a trailing edge of the negative-polarity pulse current I_{TX}.

In particular, by inserting a period in which both the first switch swp and the second switch swn are turned on so as to fix the voltages at the set terminal and the reset terminal, such an arrangement is capable of preventing a state transition from occurring in the latch circuit, thereby further stabilizing the circuit operation.

### Example 4

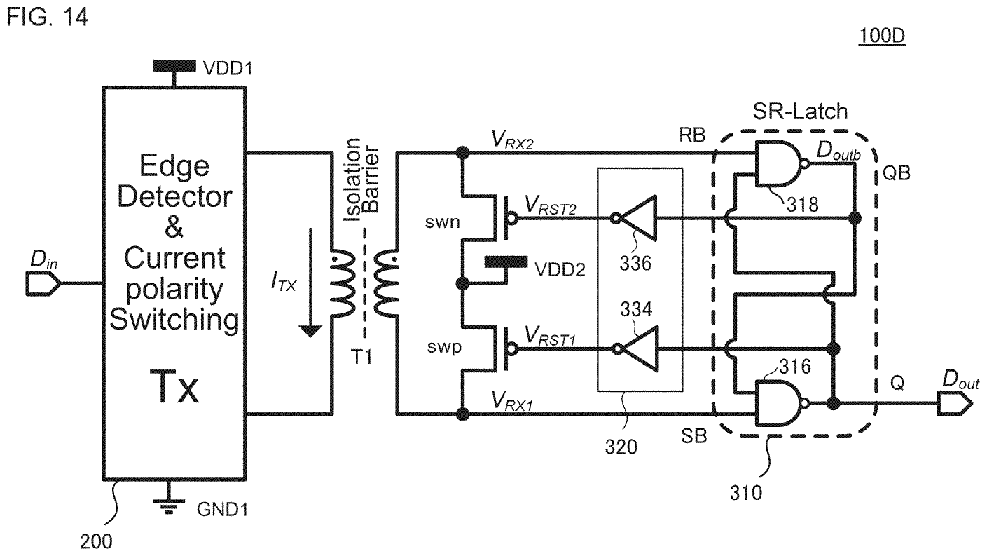

Description has been made in the examples 1 through 3 regarding an arrangement in which, as the common voltage V_{COM}, the ground voltage GND2 is employed. However, the present invention is not restricted to such an arrangement. FIG. 14 is a circuit diagram of a transmission circuit 100D according to an example 4. In the example 4, as the common voltage V_{COM}, the power supply voltage VDD2 is employed. Furthermore, the first switch swp and the second switch swn are each configured as a PMOS transistor.

In the example 4, the latch circuit 310 includes a first NAND gate 316 and a second NAND gate 318 cross-coupled to each other. The latch circuit 310 employs a negative logical system. When the voltage V_{RX1} at the set terminal SB transits from high to low, the latch circuit 310 is set. When the voltage V_{RX2} at the reset terminal RB transits from high to low, the latch circuit 310 is reset.

The switch control unit 320D includes a third inverter 334 and a fourth inverter 336. The third inverter 334 is arranged such that the output Dₒᵤₜ of the latch circuit 310 is received via its input node and its output node is coupled to the gate of the first switch swp. The fourth inverter 336 is arranged such that the inverted output signal D_{outb} of the latch circuit 310 is received via its input node and its output node is coupled to the gate of the second switch swn.

The transmitting circuit 200 generates a current signal I_{TX} using a non-pulse transmission method.

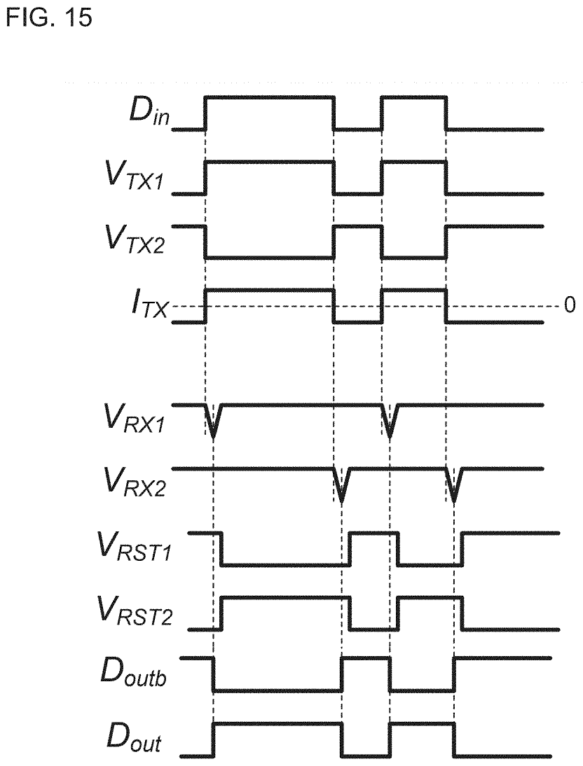

FIG. 15 is a time chart showing the operation of the transmission circuit 100D shown in FIG. 14. As shown in this drawing, with an arrangement in which the power supply voltage VDD2 is employed as the common voltage V_{COM}, such an arrangement is also capable of providing signal transmission as with an arrangement in which the ground voltage GND2 is employed as the common voltage V_{COM}.

In a case in which the latch circuit 310 is configured as a NAND latch circuit, by appropriately designing the signal logical system, such an arrangement is also capable of providing signal transmission as with an arrangement in which the latch circuit 310 is configured as a NOR latch circuit.

### Example 5

The transmission circuit may be configured using a pulse transmission method with the example 4 as a base. In this case, the inverters 334 and 336 may be each replaced by an inverting delay circuit having a delay amount of the pulse width or more.

### Example 6

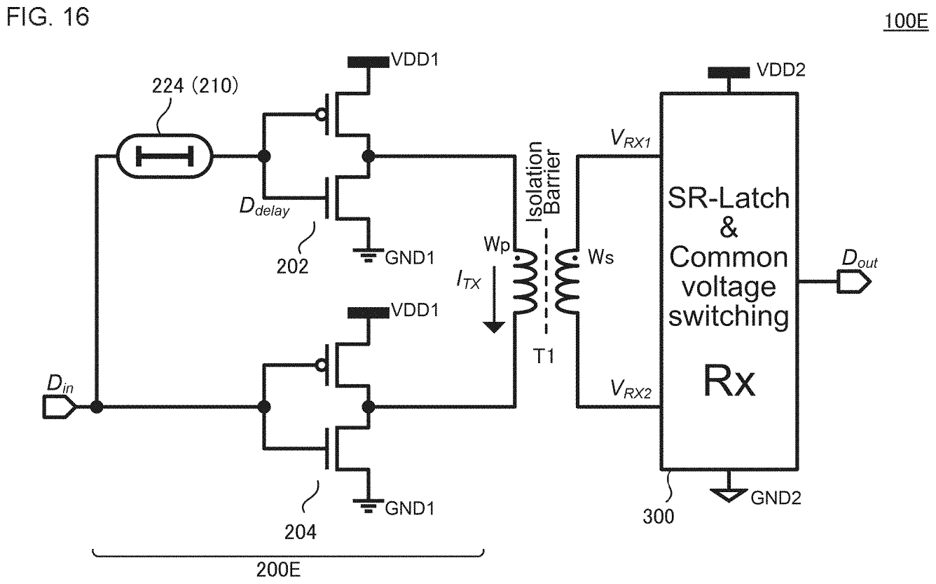

FIG. 16 is a circuit diagram of a transmission circuit 100E according to an example 6. A pre-driver 210E of the transmitting circuit 200E includes a delay circuit 224 that delays the input signal Dᵢₙ. The first output stage 202 is controlled according to the output of the delay circuit 224. The second output stage 204 is controlled according to the input signal Dᵢₙ.

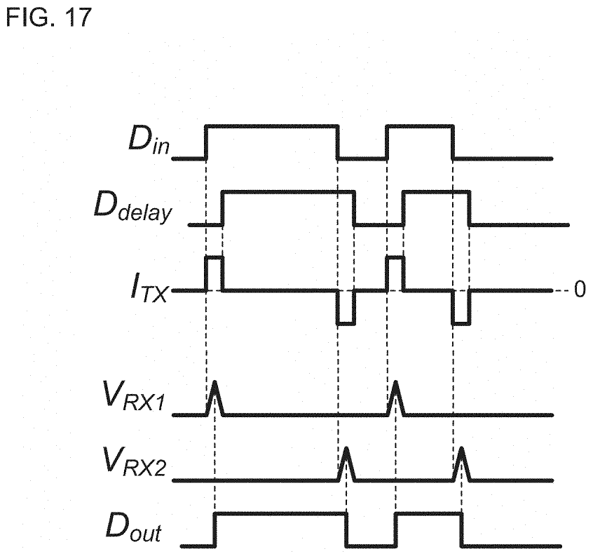

FIG. 17 is a time chart showing the operation of the transmission circuit 100E shown in FIG. 16. With the example 6, this allows the number of transistor state transitions to be reduced. Furthermore, narrow pulses are not used in the signal paths up to the first output stage 202 and the second output stage 204. Accordingly, this allows power consumption to be reduced and enables high-speed data transmission.

### Example 7

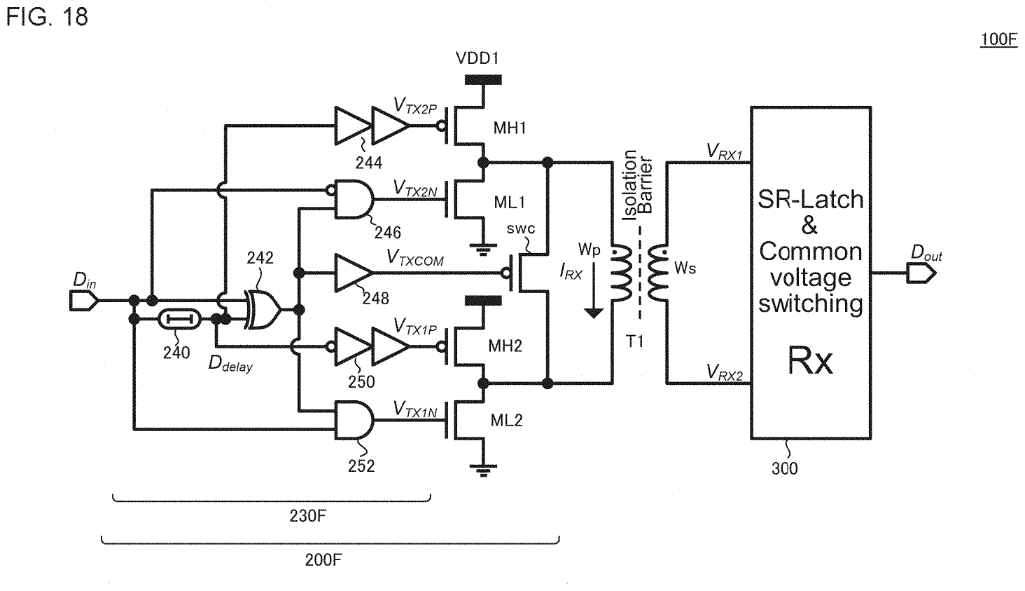

FIG. 18 is a circuit diagram of a transmission circuit 100F according to an example 7. In the first output stage 202 of a transmitting circuit 200F, the high-side transistor MH1 and the low-side transistor ML1 are arranged such that their gates are independent. Furthermore, in the second output stage 204, the high-side transistor MH2 and the low-side transistor ML2 are arranged such that their gates are independent.

Furthermore, the transmitting circuit 200F includes a common transistor swc coupled in parallel with the primary winding Wp of the transformer T1.

The pre-driver 230F drives the first high-side transistor MH1, the first low-side transistor ML1, the second high-side transistor MH2, the second low-side transistor ML2, and the common transistor swc according to the input signal Dᵢₙ.

The pre-driver 230F includes a delay circuit 240, a NOR gate 242, a buffer 244, an AND gate 246, a buffer 248, a buffer 250, and an AND gate 252.

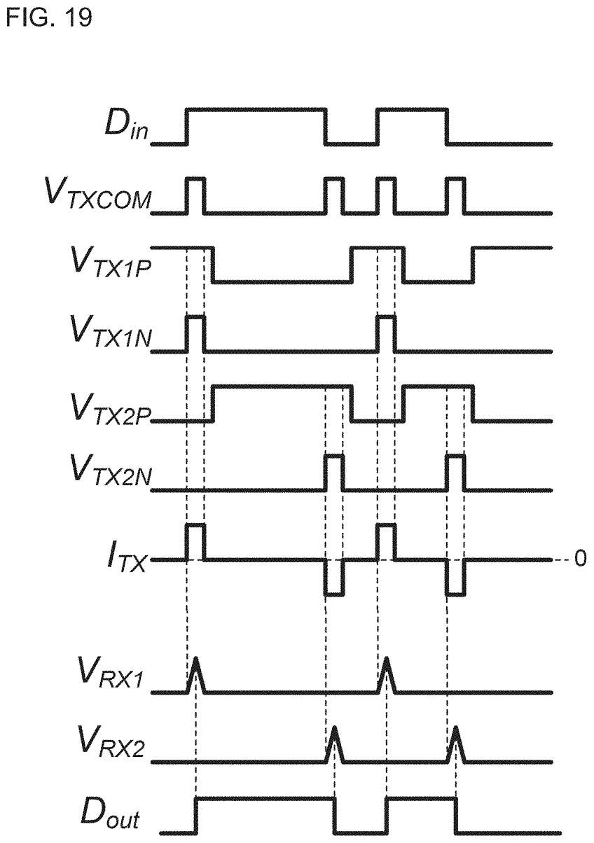

FIG. 19 is a time chart showing the operation of the transmission circuit 100F shown in FIG. 18. In the example 7, only the low-side transistors ML1 and ML2 are pulse driven. On the other hand, the high-side transistors MH1 and MH2 are not pulse driven. This allows the driving capacitance of the pre-driver 230F to be reduced, thereby allowing power consumption to be reduced.

Next, description will be made regarding the mounting of the transmission circuit 100.

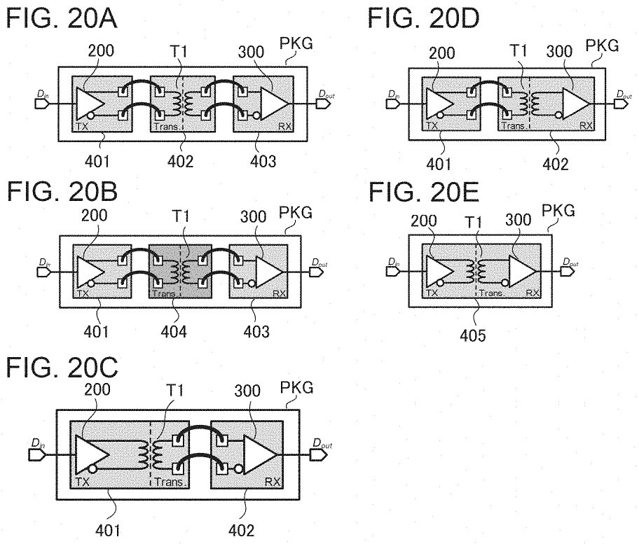

FIGS. 20A through 20E are diagrams each showing a first mounting example of the transmission circuit 100. In the mounting examples shown in FIGS. 20A through 20E, the transmission circuit 100 is housed in a single package PKG.

As shown in FIG. 20A, the primary-side transmitting circuit 200, the transformer T1, and the secondary-side receiving circuit 300 may be configured as different dies (semiconductor chips) 401, 402, and 403, respectively. In this case, the transformer T1 is configured as a pattern on a silicon die.

As shown in FIG. 20B, the transformer T1 may be configured as a pattern on a printed circuit board 404. Also, the transformer T1 may be configured as a discrete component mounted on the printed circuit board 404.

As shown in FIG. 20C, the transmitting circuit 200 and the transformer T1 may be formed on the first die 401, and the receiving circuit 300 may be formed on the second die 402.

Also, as shown in FIG. 20D, the transmitting circuit 200 may be formed on the first die 401, and the transformer T1 and the receiving circuit 300 may be formed on the second die 402.

Also, as shown in FIG. 20E, the transmitting circuit 200, the transformer T1, and the receiving circuit 300 may be formed on the same die 405. In a case in which the transmitting circuit 200 and the receiving circuit 300 are formed on the same die, such an arrangement requires a process that enables electrical isolation, such as Silicon-on-Insulator (SOI). This involves a reduction of electrical breakdown resistance.

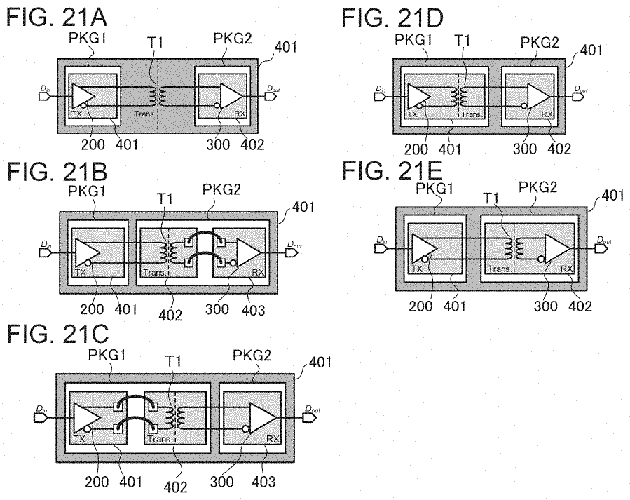

FIGS. 21A through 21E are diagrams each showing a second mounting example of the transmission circuit 100. In the mounting examples shown in FIGS. 21A through 21E, the transmission circuit 100 is configured in the form of two divided packages PKG1 and PKG2 mounted on a single printed circuit board 410.

FIG. 21A shows an arrangement in which the die 401 on which the transmitting circuit 200 is formed is housed in the package PKG1, and the die 402 on which the receiving circuit 300 is formed is housed in the package PKG2. The packages PKG1 and PGG2 and the transformer T1 are mounted on the printed circuit board 410. The transformer T1 may be configured as a discrete component. Also, the transformer T1 may be configured as a pattern on the printed circuit board 410.

FIG. 21B shows an arrangement in which the die 401 on which the transmitting circuit 200 is formed is housed in the package PKG1, and the die 402 on which the transformer T1 is formed and the die 403 on which the receiving circuit 300 is formed are housed in the package PKG2. The packages PKG1 and PKG2 are mounted on the printed circuit board 410.

FIG. 21C shows an arrangement in which the die 401 on which the transmitting circuit 200 is formed and the die 402 on which the transformer T1 is housed in the package PKG1, and the die 403 on which the receiving circuit 300 is formed is housed in the package PKG2. The packages PKG1 and PGK2 are mounted on the printed circuit board 410.

FIG. 21D shows an arrangement in which the die 401 on which the transmitting circuit 200 and the transformer T1 are formed is housed in the package PKG1 and the die 402 on which the receiving circuit 300 is formed is housed in the package PKG2. The packages PKG1 and PKG2 are mounted on the printed circuit board 410.

FIG. 21E shows an arrangement in which the die 401 on which the transmitting circuit 200 is formed is housed in the package PKG1 and the die 402 on which the transformer T1 and the receiving circuit 300 are formed is housed in the package PKG2. The packages PKG1 and PKG2 are mounted on the printed circuit board 410.

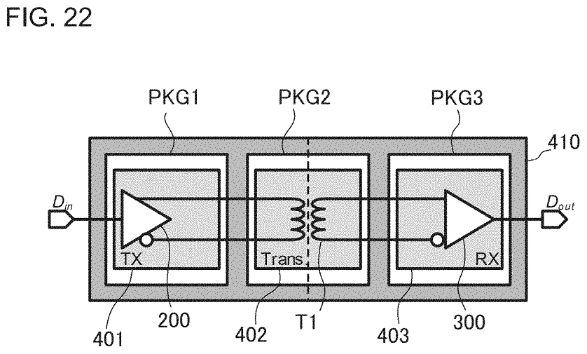

FIG. 22 shows a third mounting example of the transmission circuit 100. The transmission circuit 100 is configured in the form of three divided packages PKG1, PKG2, and PKG3 mounted on a single printed circuit board 410. Specifically, the transmitting circuit 200, the transformer T1, and the receiving circuit 300 are individually formed on separate dies 401, 402, and 403, respectively. The three dies 401, 402, and 403 are housed in the separate packages PKG1, PKG2, and PKG3, respectively. The packages PKG1 through PKG3 are mounted on the printed circuit board 410.

Description has been made regarding the present invention with reference to the embodiments using specific terms. However, the above-described embodiments show only an aspect of the mechanisms and applications of the present invention. Rather, various modifications and various changes in the layout can be made without departing from the spirit and scope of the present invention defined in appended claims.

What is claimed is:

1. A transmission circuit comprising:
a transformer comprising a primary winding and a secondary winding;
a transmitting circuit coupled to the primary winding of the transformer, and structured to transmit a current signal to the primary winding with a polarity that changes in response to a change of a level of an input signal;
a latch circuit having a set terminal coupled to one end of the secondary winding of the transformer, and a reset terminal coupled to the other end of the secondary winding of the transformer;
a first switch coupled between a common voltage node at which a common voltage occurs and the set terminal, and structured to turn on when an output of the latch circuit is high; and
a second switch coupled between the common voltage node and the reset terminal, and structured to turn on when the output of the latch circuit is low.

2. The transmission circuit according to claim 1, wherein the current signal is set to a first polarity during a period in which the input signal is set to a first level and is set to a second polarity during a period in which the input signal is set to a second level.

3. The transmission circuit according to claim 1, wherein the current signal includes a pulse current having a first polarity that corresponds to a positive edge of the input signal and a pulse current having a second polarity that corresponds to a negative edge of the input signal.

4. The transmission circuit according to claim 3, further comprising a switch control unit structured to control the first switch and second switch according to a state of the latch circuit,
and wherein, after a transition of a pulse current having the first polarity, the switch control unit turns off the second switch,
and wherein, after a transition of a pulse current having the second polarity, the switch control unit turns off the first switch.

5. The transmission circuit according to claim 4, wherein when a predetermined time period elapses after the first switch turns on, the switch control unit turns off the second switch,
and wherein when a predetermined time period elapses after the second switch turns on, the switch control unit turns off the first switch.

6. The transmission circuit according to claim 1, wherein, as the common voltage, a ground voltage is employed,
and wherein the first switch and the second switch are each structured as an NMOS transistor.

7. The transmission circuit according to claim 1, wherein, as the common voltage, the first switch and the second switch are each structured as a PMOS transistor.

8. The transmission circuit according to claim 1, wherein the latch circuit comprises a first NAOR gate and a second NAOR gate cross-coupled to each other.

9. The transmission circuit according to claim 1, wherein the latch circuit comprises a first NAND gate and a second NAND gate cross-coupled to each other.

10. The transmission circuit according to claim 1, wherein, as the common voltage, a ground voltage is employed,
wherein the first switch and the second switch are each configured as an NMOS transistor,
and wherein the transmission circuit further comprises:
a first inverter having an output node receiving an inverted output signal of the latch circuit, and an output node coupled to a gate of the first switch; and
a second inverter arranged having an input node receiving an output signal of the latch circuit, and an output node coupled to a gate of the second switch.

11. The transmission circuit according to claim 1, wherein, as the common voltage, a ground voltage is employed,
wherein the first switch and the second switch are each configured as an NMOS transistor,
and wherein the transmission circuit further comprises:
a first NAND gate having a first input node receiving an inverted output signal of the latch circuit, and an output node coupled to a gate of the first switch;
a first delay circuit structured to delay an output of the first NAND gate;
a second NAND gate having a first input node receiving an output signal of the latch circuit, a second input node receiving an output of the first delay circuit, and an output node coupled to a gate of the second switch; and
a second delay circuit structured to delay an output of the second NAND gate, and to supply the output thus delayed to the second input node of the first NAND gate.

12. The transmission circuit according to claim 1, wherein, as the common voltage, a power supply voltage is employed,
wherein the first switch and the second switch are each configured as a PMOS transistor,
and wherein the transmission circuit further comprises:
a third inverter having an input node receiving an output signal of the latch circuit, and an output node coupled to a gate of the first switch; and
a fourth inverter having an input node receiving an inverted output signal of the latch circuit, and an output node coupled to a gate of the second switch.

13. The transmission circuit according to claim 3, wherein the transmitting circuit comprises:
a first output stage structured as a push-pull output stage, and having an output node coupled to one end of the first winding;
a second output stage structured as a push-pull output stage, and having an output node coupled to the other end of the primary winding; and
a pre-driver structured to control the first output stage and the second output stage with opposite polarities according to the input signal.

14. The transmission circuit according to claim 13, wherein the pre-driver comprises:
a delay circuit structured to delay the input signal;
a NOR gate structured to generate an exclusive logical OR of the input signal and an output of the delay circuit;
a first AND gate structured to drive the first output stage based on a logical AND of an inverted signal of the input signal and an output of the delay circuit; and
a second AND gate structured to drive the second output stage based on a logical AND of the input signal and the output of the delay circuit.

15. The transmission circuit according to claim 13, wherein the pre-driver comprises a delay circuit structured to delay the input signal,
and wherein the pre-driver controls the first output stage according to an output of the delay circuit and controls the second output stage according to the input signal.

16. The transmission circuit according to claim 1, wherein the transmitting circuit comprises:
a first high-side transistor having a drain coupled to one end of the primary winding, and a source thereof receives a power supply voltage;
a first low-side transistor having a drain coupled to one end of the primary winding, and a source thereof is grounded;
a second high-side transistor having a drain coupled to the other end of the primary winding, and a source thereof receives the power supply voltage;
a second low-side transistor having a drain coupled to the other end of the primary winding, and a source thereof is grounded;
a common transistor coupled in parallel with the primary winding; and
a pre-driver structured to drive the first high-side transistor, the first low-side transistor, the second high-side transistor, the second low-side transistor, and the common transistor according to the input signal.
